(19) United States
(12) Patent Application Publication
(10) Pub. No.: US 2013/0059423 A1
(43) Pub. Date: Mar. 7, 2013

(54) METHOD OF MANUFACTURING SEMICONDUCTOR DEVICE

(71) Applicants: Tomohiko KUDO, Tokyo (JP); Kiyonori OYU, Tokyo (JP)

(72) Inventors: Tomohiko KUDO, Tokyo (JP); Kiyonori OYU, Tokyo (JP)

(73) Assignee: ELPIDA MEMORY, INC., Tokyo (JP)

(21) Appl. No.: 13/594,022

(22) Filed: Aug. 24, 2012

(30) Foreign Application Priority Data
Sep. 5, 2011 (JP) 2011-192343

(51) Int. Cl. H01L 21/336

(52) U.S. Cl. 438/270; 257/E21.41

(57) ABSTRACT

Provided is a method of manufacturing a semiconductor device, including: forming an active region surrounded by an element isolation region in a substrate; forming a pair of gate trenches in the active region; forming a pair of gate electrodes by embedding a conductor in the gate trenches; forming an implanted layer by implanting ions into a substrate surface between the gate electrodes; and thermally diffusing impurities of the implanted layer at least to a depth of bottom portions of the gate trenches by a transient enhanced diffusion method to form a diffusion layer region between the gate electrodes at least to a depth of bottom portions of the gate electrodes.

This application is based upon and claims the benefit of priority from Japanese Patent Application No. 2011-192343, filed on Sep. 5, 2011, the disclosure of which is incorporated herein in its entirety by reference.

### TECHNICAL FIELD

This invention relates to a method of manufacturing a semiconductor device.

### BACKGROUND

As a dynamic random access memory (DRAM) has become finer in recent times, the gate length of an access transistor becomes smaller and channel leakage increases, and thus, a problem arises in that data cannot be held. In order to solve this problem, a trench gate transistor (recessed channel transistor) is used as the access transistor.

For example, Japanese Patent Unexamined Application Publication (JP-A) Nos. 2011-54629, 2011-129667, and 2005-142203, and J. Y. Kim et. al., VLSI Symposium, 2003, pp. 11-12 disclose the related art.

The above-mentioned related art has a problem in that voltage change at a gate electrode of a transistor affects a gate electrode of an adjacent transistor.

### SUMMARY

In one embodiment, there is provided a method of manufacturing a semiconductor device, including:

forming an active region surrounded by an element isolation region in a substrate;

forming a pair of gate trenches in the active region;

forming a pair of gate electrodes by embedding a conductor in the gate trenches;

forming an implanted layer by implanting ions into a substrate surface between the gate electrodes; and

thermally diffusing impurities of the implanted layer at least to a depth of bottom portions of the gate trenches by a transient enhanced diffusion method to form a diffusion layer region between the gate electrodes at least to a depth of bottom portions of the gate electrodes.

### BRIEF DESCRIPTION OF THE DRAWINGS

The above features and advantages of the present invention will be more apparent from the following description of certain preferred embodiments taken in conjunction with the accompanying drawings, in which

FIG. 1A is a top view of a memory cell portion of a DRAM according to the related art;

FIG. 1B is a sectional view taken along the line A-A′ of FIG. 1A;

FIG. 1C is a graph showing concentration distribution of impurities in the section taken along the line B-B′ of FIG. 1B;

FIGS. 2A to 2C illustrate process steps of a method of manufacturing a semiconductor device according to the related art;

FIGS. 3A to 3C illustrate process steps of the method of manufacturing the semiconductor device according to the related art;

FIGS. 4A and 4B illustrate process steps of the method of manufacturing the semiconductor device according to the related art;

FIGS. 5A to 5D illustrate process steps of the method of manufacturing the semiconductor device according to the related art;

FIG. 6A illustrate a structure of a semiconductor device according to a first embodiment of this invention, and is a top view of a memory cell portion of a DRAM;

FIG. 6B is a sectional view taken along the line A-A′ of FIG. 6A;

FIG. 6C is a graph showing concentration distribution of impurities in the section taken along the line B-B′ of FIG. 6B;

FIGS. 7A to 7C illustrate process steps of a method of manufacturing the semiconductor device according to the first embodiment of this invention;

FIGS. 8A to 8C illustrate process steps of the method of manufacturing the semiconductor device according to the first embodiment of this invention;

FIGS. 9A and 9B illustrate process steps of the method of manufacturing the semiconductor device according to the first embodiment of this invention;

FIGS. 10A to 10C illustrate process steps of the method of manufacturing the semiconductor device according to the first embodiment of this invention;

FIGS. 11A and 11B illustrate process steps of the method of manufacturing the semiconductor device according to the first embodiment of this invention;

FIG. 12A illustrate a structure of a semiconductor device according to a second embodiment of this invention, and is a top view of a memory cell portion of a DRAM;

FIG. 12B is a sectional view taken along the line A-A′ of FIG. 12A;

FIG. 12C is a graph showing concentration distribution of impurities in the section taken along the line B-B′ of FIG. 12B;

FIGS. 13A to 13C illustrate process steps of a method of manufacturing the semiconductor device according to the second embodiment of this invention;

FIGS. 14A and 14B illustrate process steps of the method of manufacturing the semiconductor device according to the second embodiment of this invention;

FIG. 15A is a graph showing difference in impurities concentration distribution between conventional annealing and annealing using transient enhanced diffusion according to this invention;

FIG. 15B is a graph showing the relationship between the amount of transient enhanced diffusion and the amount of lattice damage;

FIG. 16A is a graph showing P concentration distribution in a Si substrate when P is ion-implanted with various doses and annealing is carried out at a temperature for a time period with which transient enhanced diffusion occurs;

FIG. 16B is a graph showing the relationship between the amount of lattice damage and the amount of implanted ions;

FIG. 16C illustrates a state when the dose is 2E14 (atoms/cm²) or less;

FIG. 16D illustrates a state when the dose is 5E14 (atoms/cm²) or less; and

FIG. 17 is a graph showing a region A of annealing temperature and annealing time used in this invention.

### DESCRIPTION OF EXEMPLARY EMBODIMENTS

The present invention will be now described herein with reference to illustrative exemplary embodiments. Those skilled in the art will recognize that many alternative embodiments can be accomplished using the teachings of the present invention and that the invention is not limited to the exemplary embodiments illustrated for explanatory purposes.

### (Related Art)

First, in order to clarify the features of this invention, the related art is described.

As described above, as a dynamic random access memory (DRAM) has become finer, the gate length of an access transistor becomes smaller and channel leakage increases, and as a result, a problem arises in that data cannot be held. In order to solve this problem, a trench gate transistor (recessed channel transistor) is used as the access transistor (see, for example, J. Y. Kim et. al., VLSI Symposium, 2003, pp. 11-12).

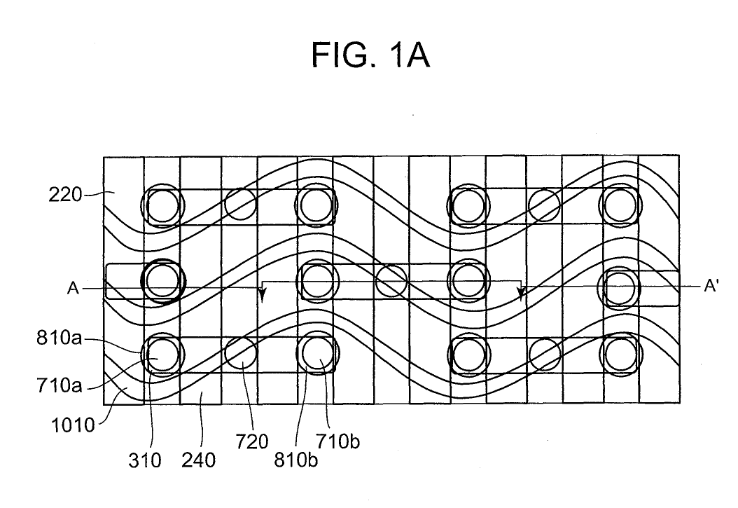

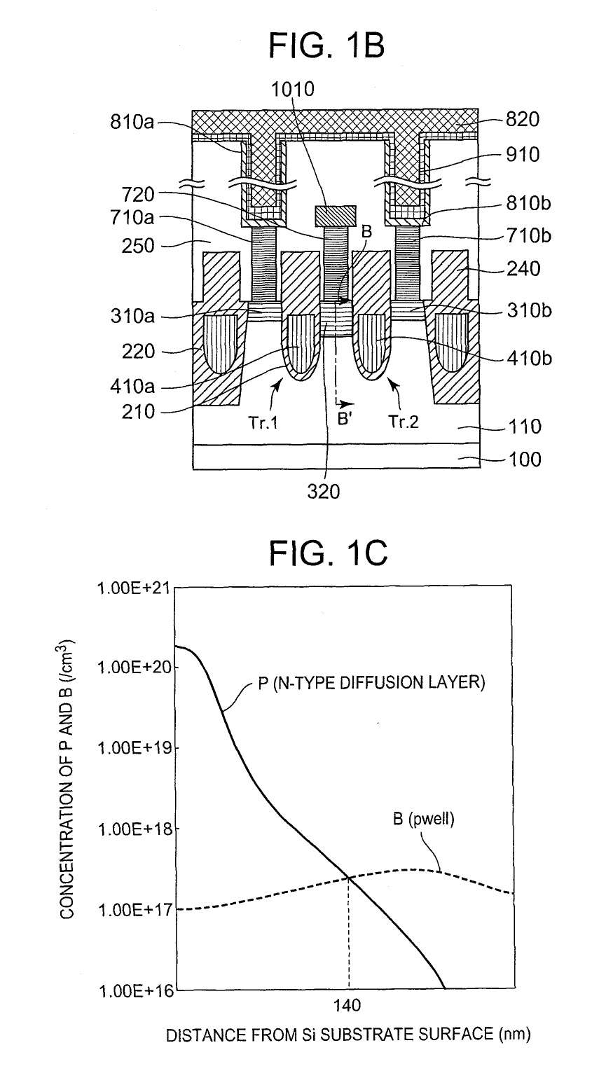

The structure of the recessed channel transistor is illustrated in FIGS. 1A to 1C.

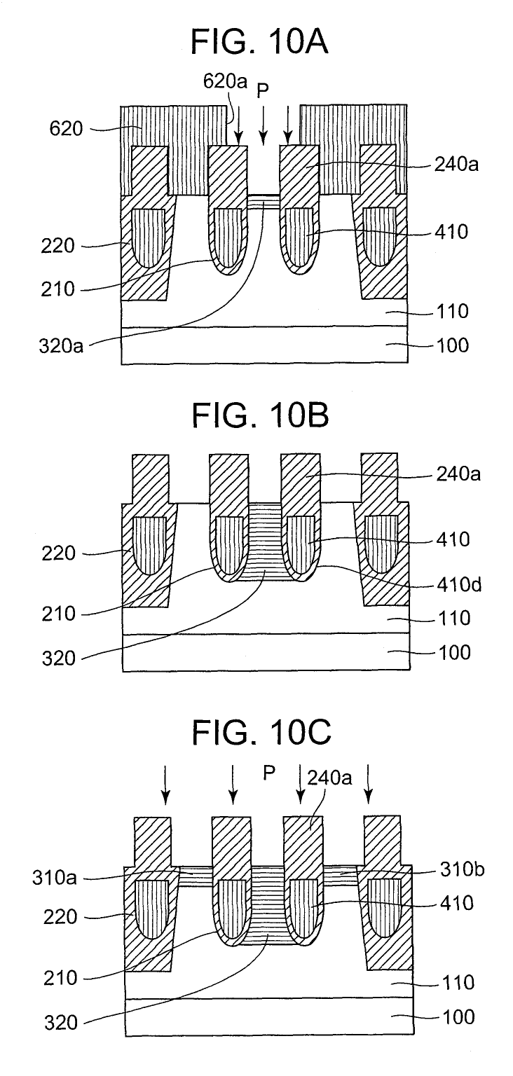

FIG. 1A is a top view of a memory cell portion of a DRAM. FIG. 1B is a sectional view taken along the line A-A′ of FIG. 1A. FIG. 10 shows concentration distribution of impurities in the section taken along the line B-B′ of FIG. 1B.

As illustrated in FIGS. 1A and 1B, the DRAM includes a p-well 110 formed of p-type impurities such as boron in a silicon substrate 100, element isolation regions 220 which are formed of an insulating film such as an oxide film and which are at a depth of 300 nm from a Si surface, a gate insulating film 210 formed on surfaces of holes dug in the silicon substrate 100 and the element isolation regions 220 by dry etching, gate electrodes 410a and 410b which are formed by filling the holes with TiN, W/TiN, or the like and which are at a depth of 200 nm from the Si surface, an oxide film 240 formed on the gate electrodes 410a and 410b, diffusion layer regions 310a and 310b formed of n-type impurities such as phosphorus between the gate electrodes 410a and 410b and the element isolation regions 220, respectively, a diffusion layer region 320 which is formed of n-type impurities such as phosphorus between the adjacent gate electrodes 410a and 410b and which is deeper than the diffusion layer regions 310a and 310b, cell contacts (capacitive contact plugs) 710a and 710b formed on the diffusion layer regions 310a and 310b, respectively, and a bit contact (bit contact plug) 720 formed on the diffusion layer region 320.

Further, lower electrodes 810a and 810b of a capacitor are formed of TiN or the like on the cell contacts 710a and 710b, respectively, a capacitive film 910 is formed of Al₂O₃ or the like on the lower electrodes 810a and 810b, a capacitive plate 820 is formed of TiN or the like on the capacitive film 910, and a bit line 1010 is formed on the bit contact 720.

In this case, two cell transistors are formed. A first cell transistor Tr.1 is formed by the left gate electrode 410a, a source region of the left diffusion layer region 310a, and a drain region of the diffusion layer region 320. A second cell transistor Tr.2 is formed by the right gate electrode 410b, a source region of the right diffusion layer region 310b, and the drain region of the diffusion layer region 320.

A channel region of the first cell transistor Tr.1 is a silicon region from an end of the drain region of the diffusion layer region 320 to an end of the source region of the left diffusion layer region 310a along the gate electrode 410a and the gate insulating film 210. A channel region of the second cell transistor Tr.2 is a silicon region from the other end of the drain region of the diffusion layer region 320 to an end of the source region of the right diffusion layer region 310b along the gate electrode 410b and the gate insulating film 210. In this case, the distance between the gate electrodes 410a and 410b adjacent to each other is 50 nm, the width of the gate electrodes 410a and 410b is also 50 nm, and the distances between the gate electrodes 410a and 410b and the element isolation regions 220, respectively, are also 50 nm.

As shown in FIG. 10, in the impurities concentration distribution in the diffusion layer region 320, according to the concentration distribution of boron in the p-well and the concentration distribution of phosphorus in the diffusion layer region, a pn junction boundary of the diffusion layer is at a depth of 140 nm from the silicon surface at which the boron concentration distribution and the phosphorus concentration distribution intersect each other. This depth of 140 nm corresponds to a lower end of the diffusion layer region 320 illustrated in FIG. 1B. In this case, the impurities concentration distribution of the deep diffusion layer region 320 is formed by channeling when the ions are implanted by an ion implantation method. More specifically, after the ions are implanted, when annealing is carried out for the purpose of activating the impurities implanted in the silicon substrate 100, conditions in which the temperature is 1,000° C. and the time period is 10 seconds are used.

Conventionally, when a source/drain diffusion layer is formed, annealing conditions at a high temperature for a short time period as described above are often used in order that the depth of the diffusion layer is not changed by heat treatment after the ion implantation. In this case, there is almost no difference between the impurities concentration distribution after the impurities are implanted and before the annealing is carried out and the impurities concentration distribution after the impurities are implanted and after the annealing is carried out, and only activation of the implanted impurities is attained. Therefore, the depth of the diffusion layer does not depend on the annealing conditions, and depends on channeling which in turn depends on the acceleration energy when the ions are implanted.

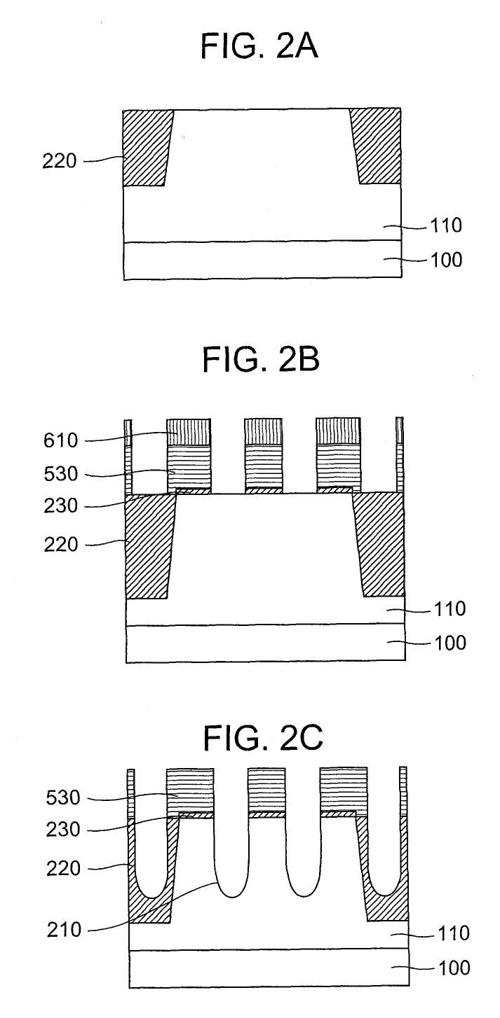

A method of manufacturing the semiconductor device illustrated in FIG. 1B is now described with reference to FIGS. 2A to 5D.

First, as illustrated in FIG. 2A, the p-well 110 and the element isolation regions 220 are formed on the silicon substrate 100. Then, as illustrated in FIG. 2B, a pad oxide film 230 is formed, a nitride film 530 and a resist 610 are formed on the pad oxide film 230, and patterning and etching are carried out.

Then, as illustrated in FIG. 2C, the silicon substrate 100 and the element isolation regions 220 are etched with use of the nitride film 530 as the mask.

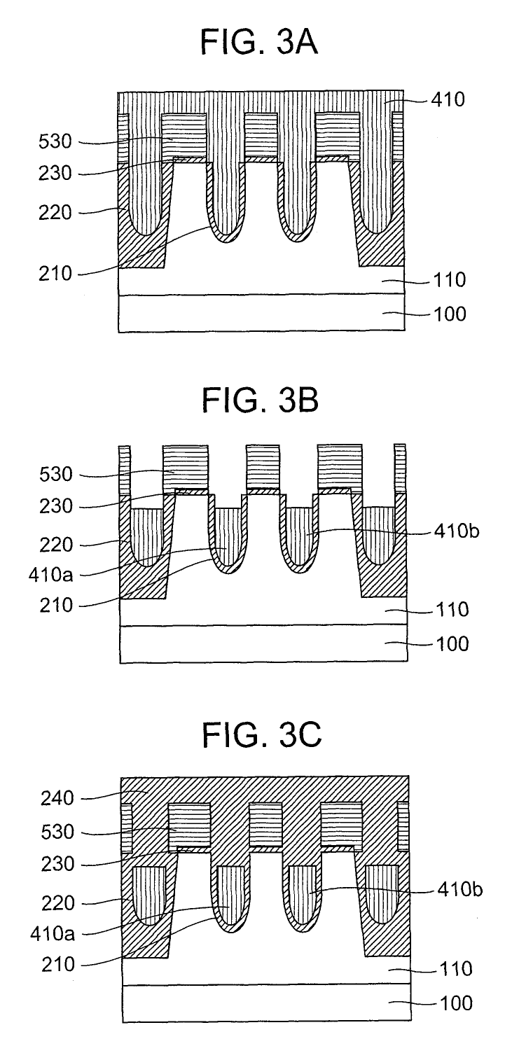

Next, as illustrated in FIG. 3A, the gate insulating film 210 and a gate electrode material 410 are formed in trenches formed by etching in the silicon substrate 100 and the element isolation regions 220.

Then, as illustrated in FIG. 3B, etching back is carried out to form the gate electrodes 410a and 410b in the trenches.

Then, as illustrated in FIG. 3C, the oxide film 240 is formed.

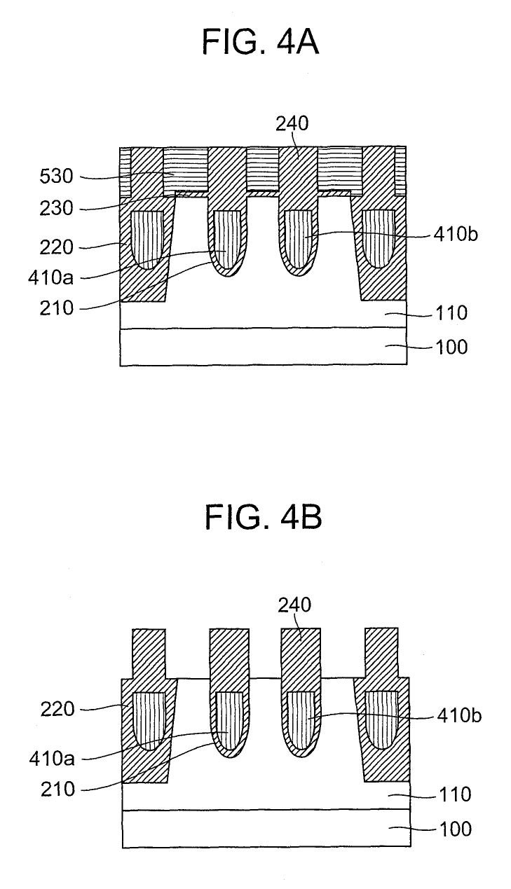

Next, as illustrated in FIG. 4A, the oxide film 240 is polished by chemical mechanical polishing (CMP).

Then, as illustrated in FIG. 4B, the nitride film 530 is removed by wet etching.

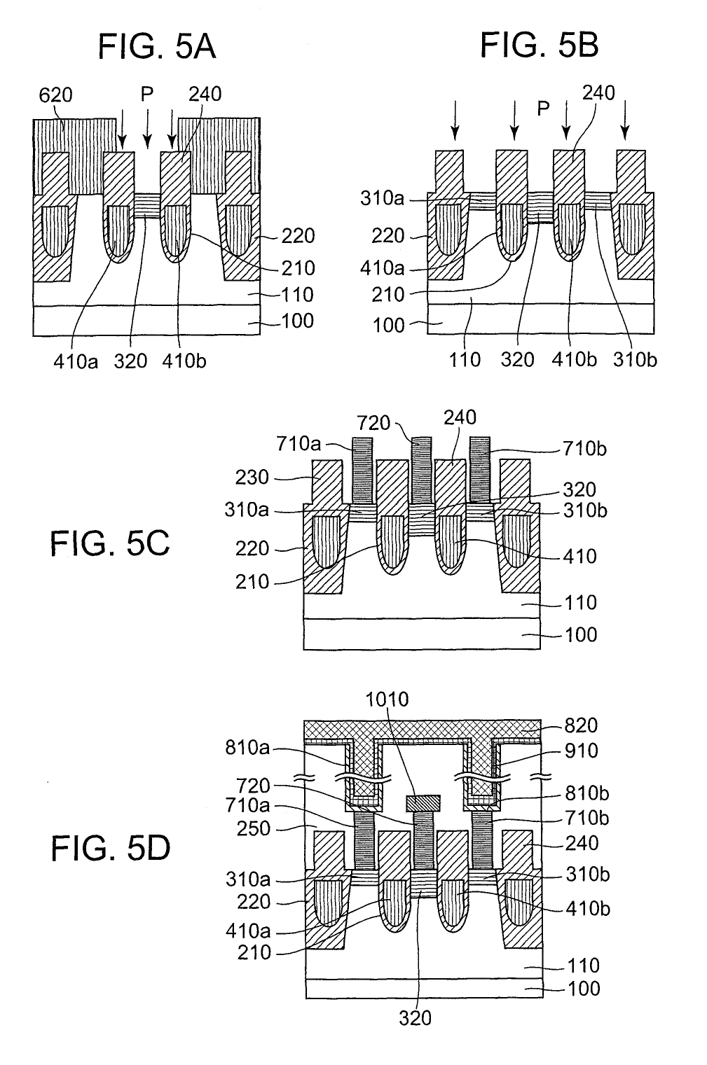

Next, as illustrated in FIG. 5A, a resist pattern which has an opening only in a portion in which the diffusion layer region 320 is to be formed is prepared, and phosphorus is implanted at an angle at which channeling distribution may be obtained.

Then, as illustrated in FIG. 5B, phosphorus is implanted to form the diffusion layer regions 310a and 310b.

Then, as illustrated in FIG. 5C, annealing is carried out under conditions in which the annealing temperature is 1,000° C. and the annealing time is 10 seconds to form the capacitive contact plugs 710a and 710b and the bit line contact plug 720.

Then, as illustrated in FIG. 5D, the bit line 1010 is formed on the bit line contact plug 720 by forming a W and then carrying out patterning. After an interlayer insulating film 250 is formed, capacitor forming portions are formed by digging holes by etching, a titanium nitride film (TiN) is formed, patterning is carried out, and after that, etching is carried out to form the lower electrodes 810a and 810b of the capacitor on the capacitive contact plugs 710a and 710b, respectively. The capacitive film 910 of aluminum oxide (Al₂O₃) is formed on the lower electrodes 810a and 810b and a capacitive plate electrode 820 of TiN is formed on the capacitive film 910.

The reason why diffusion layer region 320 which is deeper than the diffusion layer regions 310a and 310b is formed as illustrated in FIG. 1B is that part of the opposed channel regions of the first transistor Tr.1 and the second transistor Tr.2 are replaced by the deep diffusion layer, and thus, compared with a case where the diffusion layer region 320 is a shallow diffusion layer which is the same as the diffusion layer regions 310a and 310b, the effect of voltage change at the gate electrode 410a of the first transistor Tr.1 on the channel region of the second transistor Tr.2 is expected to be reduced.

However, when a deep diffusion layer is formed by ion implantation using channeling, an impurity region in which, for example, the phosphorus concentration is 3E17 (/cm³) or lower is formed between the gate electrodes 410a and 410b adjacent to each other so as to overlap the p-well. The concentration of the n-type impurities and the concentration of the p-type impurities become at the same level, and, as a result, a low concentration n-type impurity region is formed. The concentration of the n-type impurities is low, and thus, when voltage is applied, a depletion layer is more liable to be formed. Therefore, when voltage applied to the gate electrode 410a of the first transistor Tr.1 is changed, electrical characteristics of the second transistor Tr.2 are greatly affected through the depletion layer region formed below the diffusion layer region 320.

For example, even if the second transistor Tr.2 is in an OFF state by the right gate electrode 410b, the threshold value is lowered under the effect of the gate electrode of the first transistor Tr.1, and the off-leakage current increases. The above-mentioned problem becomes more conspicuous as the semiconductor device becomes finer and the gate distance and the gate width become smaller than 50 nm. More specifically, the gate of the first transistor Tr.1 and the gate of the second transistor Tr.2 come nearer to each other, and thus, the threshold value of the second transistor Tr.2 is lowered under the effect of the gate electrode 410a of the first transistor Tr.1, and the off-leakage current further increases.

Further, in the recessed channel transistor, channel regions are formed in a silicon region along the gate insulating film 210 on both sides of and below the gate electrodes 410a and 410b, respectively, and thus, the channels are longer than required. With the expectation that the performance of the transistors is improved, the diffusion layer region 320 is set to be deeper by channeling and the channel lengths are set to be small. However, the concentration of the n-type impurities in the diffusion layer which is set to be deeper by channeling is low, and further, the p-type impurities in the p-well also exist therein. Therefore, the parasitic resistance of the diffusion layer region 320 becomes higher, and thus, although the channel lengths are set to be small, the ON current does not increase due to the increase of the parasitic resistance, and the performance is not improved.

Further, in the method of manufacturing a deep diffusion layer by channeling, the diffusion layer cannot be formed uniformly in the wafer surface with high concentration down to below the gate electrodes 410a and 410b.

When ions are implanted deep by using channeling distribution of ion implantation, the formation of the diffusion layer is greatly affected by the state of the surface when the ions are implanted, and the implantation distribution itself cannot become uniform in the silicon substrate surface. Further, a beam from an implanter is inclined by 1 degree, which also affects the formation of the diffusion layer. In summary, due to the insufficient uniformity in the silicon substrate, the manufacturing yield of a DRAM using a recessed channel transistor is reduced.

As an alternative, there is a method in which the ion implantation energy is set to be higher and a deeper diffusion layer is formed in the diffusion layer region 320. However, with this method, the ions are diffused and implanted also into the adjacent diffusion layer regions 310a and 310b in each of which a shallow diffusion layer is to be formed, and thus, the threshold value is lowered and the junction field increases, and the off-leakage current and the diffusion layer leakage current increase. The above-mentioned problems of diffusion and implantation become more conspicuous as the semiconductor device becomes finer and the gate distance and the gate width become smaller than 50 nm, because the impurities implanted into the diffusion layer region 320 with high energy also enter the diffusion layer regions 310a and 310b.

In view of the above-mentioned problems of the related art, according to this invention, there are provided a semiconductor device and a method of manufacturing the same which are capable of preventing voltage change at a gate electrode of a transistor from affecting a gate electrode of an adjacent transistor by implanting high concentration impurities ions in a region having such a depth that does not cause diffusion and implantation, that is, in a shallow region which is in proximity to a substrate surface, and after that, carrying out annealing at a temperature at which transient enhanced diffusion to be described below occurs, thereby thermally diffusing the implanted impurities and forming a deep diffusion layer only in a substrate region below a bit line contact plug. Further, there are provided a semiconductor device and a method of manufacturing the same which are capable of improving the performance of a transistor.

### FIRST EXEMPLARY EMBODIMENT

Next, a structure of a semiconductor device according to a first exemplary embodiment of this invention is described.

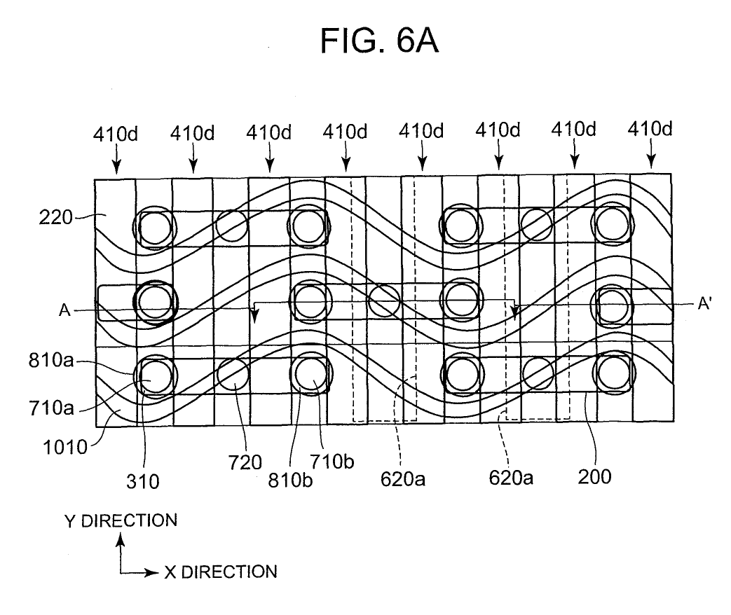

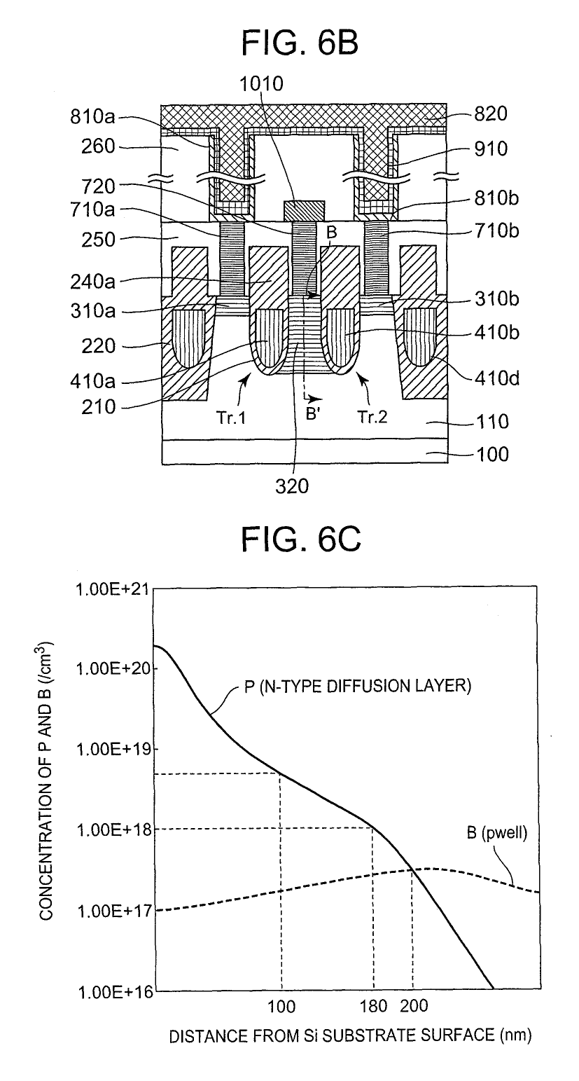

FIG. 6A is an example of a top view of a memory cell portion of a DRAM. FIG. 6B is a sectional view taken along the line A-A′ of FIG. 6A. FIG. 6C shows concentration distribution of impurities in the section taken along the line B-B′ of FIG. 6B.

In this exemplary embodiment, a case where an n-channel MOS transistor is used as a cell transistor (Tr) is described as an example. Note that, the transistor may be a p-channel MOS transistor. In that case, the conductive types of the impurities described are to be reversed for use.

In the semiconductor device according to the first exemplary embodiment of this invention, as illustrated in FIGS. 6A and 6B, a p-well 110 formed by p-type impurities such as boron (B) in a p-type single crystal silicon substrate (hereinafter, referred to as substrate) 100, element isolation regions 220 which are formed of an insulating film such as a silicon oxide film so as to be embedded at a depth of 300 nm from a substrate surface, and a plurality of active regions 200 surrounded by the element isolation regions 220 are regularly arranged in an X direction and a Y direction.

In the example illustrated in FIG. 6A, the longitudinal direction of the active regions 200 is the X direction and a bit line 1010 to be described below is serpentine, but this invention is not limited thereto. For example, the active regions 200 may be inclined with respect to the X direction and the bit line 1010 may be linearly arranged so as to extend in the X direction. Gate trenches 410d extending linearly in the Y direction are provided so that two of the gate trenches 410d intersect one active region 200. The substrate 100 forming the active regions 200 and the insulating film forming the element isolation regions 220 are alternately arranged in the Y direction below one gate trench 410d.

As illustrated in FIG. 6B, a gate insulating film 210 is formed on a surface of the substrate 100 in the gate trenches 410d. Embedded gate electrodes 410 which are a titanium nitride (TiN) single layer film, a stacked film formed by stacking tungsten (W) on titanium nitride, or the like are formed on the gate insulating film 210.

In the section illustrated in FIG. 6B, for the sake of convenience of description, the embedded gate electrodes 410 located in the active regions 200 are referred to as 410a and 410b. In this embodiment, bottom portions of the gate trenches 410d are at a depth of 200 nm from the substrate surface. A cap insulating film 240a which is a silicon nitride film is formed on the embedded gate electrodes 410 so as to protrude from the substrate surface. Shallow diffusion layer regions 310a and 310b which are formed of n-type impurities such as phosphorus (P) and which are to be source regions are formed in proximity to the surface of the substrate 100 between the embedded gate electrode 410a and one of the element isolation regions 220 and between the embedded gate electrode 410b and the other of the element isolation regions 220, respectively.

A diffusion layer region 320 to be a drain region containing n-type impurities such as phosphorus (P) is formed in the substrate 100 between the embedded gate electrode 410a and the embedded gate electrode 410b which are adjacent to each other in the X direction. The depth of the diffusion layer region 320 is same level as the depth of the bottom portions of the gate trenches 410d. A first interlayer insulating film 250 which is a silicon oxide film is formed so as to cover the entirety of the cap insulating film 240a, the active regions 200, and the element isolation regions 220. Capacitive contact plugs 710a and 710b connected to the diffusion layer regions 310a and 310b, respectively, are formed in the first interlayer insulating film 250. Further, a bit line contact plug 720 connected to the diffusion layer region 320 is formed. A second interlayer insulating film 260 is formed on the first interlayer insulating film 250. Capacitors connected to the capacitive contact plugs 710a and 710b, respectively, are formed in the second interlayer insulating film 260. The capacitors include lower electrodes 810a and 810b connected to the capacitive contact plugs, a capacitive insulating film 910 which covers the lower electrodes 810a and 810b, and a capacitive plate electrode 820 which covers the capacitive insulating film 910, respectively. On the other hand, the bit line 1010 connected to the bit line contact plug 720 is formed on the bit line contact plug 720.

In the above-mentioned structure, two cell transistors (Tr) (Tr1 and Tr2) having the embedded gate electrodes 410a and 410b, respectively, are formed in one active region 200. The first cell transistor Tr1 includes the gate insulating film 210, the embedded gate electrode 410a, the diffusion layer region 310a to be a source region, and the diffusion layer region 320 to be a drain region. Further, the second cell transistor Tr2 which is adjacent to the first cell transistor Tr1 in one active region 200 includes the gate insulating film 210, the embedded gate electrode 410b, the diffusion layer region 310b to be a source region, and the diffusion layer region 320 to be a drain region. The diffusion layer region 320 as the drain region is shared by the two transistors.

The channel region of Tr1 is a substrate surface region in contact with the gate insulating film 210 from a bottommost portion of a gate trench 410d (embedded gate electrode 410a) which is a lower end of the diffusion layer region 320 to be the drain region to a lower end of the diffusion layer region 310a to be the source region. The channel region of Tr2 is a substrate surface region in contact with the gate insulating film 210 from a bottommost portion of a gate trench 410d (embedded gate electrode 410b) which is the lower end of the diffusion layer region 320 to be the drain region to a lower end of the diffusion layer region 310b to be the source region. The width of the gate trench 410d to be formed is the minimum dimension of processing which is the limit of resolution in lithography. In this exemplary embodiment, the gate trenches 410d extending in the Y direction as straight strips are arranged so as to have a width of 50 nm and at a pitch of 100 nm. Further, two of the gate trenches 410d intersect one active region 200 having a longer side extending in the X direction so as to divide the active region 200 into three equal parts.

FIG. 6C shows impurities concentration distribution in the diffusion layer region 320. As shown in FIG. 6C, transient enhanced diffusion to be described below is used, and thus, the concentration distribution of phosphorus (n-type diffusion layer) is deeper than the phosphorus concentration distribution of the related art shown in FIG. 10. More specifically, at a depth of 100 nm from the substrate surface (upper surface of the diffusion layers), the concentration is 5E18 atoms/cm³, while, at a depth of 180 nm, the concentration is 1E18 atoms/cm³. In this embodiment, the peak concentration of boron in the p-well is 3E17 atoms/cm³, and thus, the boron concentration distribution in the p-well and the phosphorus concentration distribution in the n-type diffusion layer intersect each other at a depth of 200 nm. This intersection is a pn junction boundary, which is the depth of the diffusion layer region 320.

As described above, the diffusion layer region 320 is as deep as a lower end of the gate trenches 410d, and thus, the channel lengths of Tr1 and Tr2 become shorter, and the concentration of the impurities in the deep diffusion layer region 320 may be set to be higher, and thus, the parasitic resistance may be decreased and the ON current of the transistors may be improved. Further, the diffusion layer region 320 is an n-type impurity region having a concentration as high as 1E18 atoms/cm³ or more, and thus, even when the gate voltage of Tr1 changes, the potential distribution of the diffusion layer region 320 on the Tr2 side does not change. Therefore, operation of Tr1 does not affect the electrical characteristics of Tr2 which is adjacent to Tr1 in one active region 200.

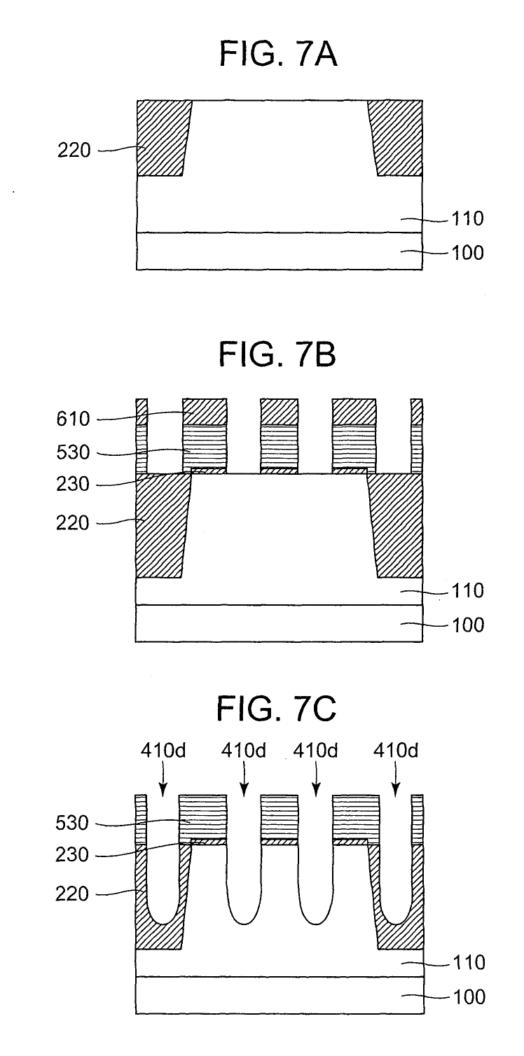

Next, a method of manufacturing the semiconductor device according to the first exemplary embodiment of this invention is described with reference to FIGS. 7A to 11B.

First, as illustrated in FIG. 7A, the p-well 110 and the element isolation regions 220 are formed on the substrate 100. As illustrated in the plan view of FIG. 6A, the element isolation regions 220 are formed by forming trenches in the surface of the substrate 100 so as to surround the plurality of island-like active regions 200 and filling the trenches with an insulating film.

Then, as illustrated in FIG. 7B, a pad oxide film 230 which is a silicon oxide film is formed, and further, a silicon oxide film 530 is formed so as to be stacked. Both the pad oxide film 230 and the silicon oxide film 530 are silicon oxide films, and thus, formation of the pad oxide film 230 may be omitted.

After that, a photoresist 610 is formed by lithography, and, as illustrated in the plan view of FIG. 6A, an opening pattern extending in the Y direction so as to intersect the active region 200 is formed in the photoresist 610. Then, the silicon oxide film 530 is dry etched with use of the photoresist 610 as the mask. This exposes the surface of the substrate 100 and of the element isolation regions 220 at the bottom of the opening pattern.

Then, as illustrated in FIG. 7C, the substrate 100 and the element isolation regions 220 which are exposed are etched with use of the silicon oxide film 530 as the mask to form the gate trenches 410d so that the bottommost portions thereof are at a depth of 200 nm from the surface of the substrate 100.

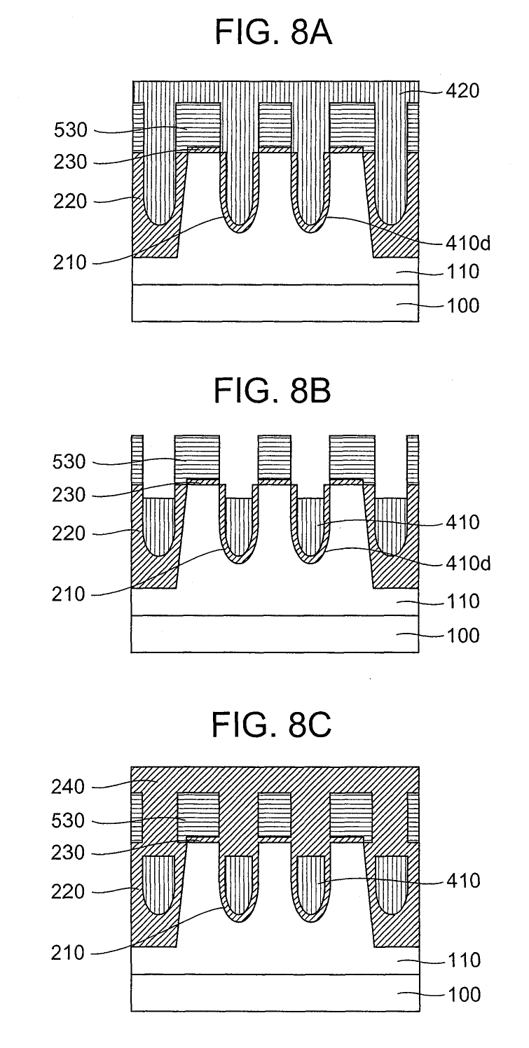

Next, as illustrated in FIG. 8A, the gate insulating film 210 which is a silicon oxide film is formed on inner surfaces of the gate trenches 410d at a thickness of 5 nm by thermal oxidation. Further, a conductor 420 is formed by CVD on the entire surface so as to fill the gate trenches 410d and so as to cover the silicon oxide film 530 used as the etching mask. As the conductor 420, metal such as a TiN single layer film, a film formed by stacking W on TiN, or the like may be used.

Then, as illustrated in FIG. 8B, etching back of the conductor 420 is carried out by dry etching to form the embedded gate electrodes 410 to be word lines of the DRAM. In this case, the etching is carried out so that upper surfaces of the embedded gate electrodes 410 are at a depth of 80 nm from the substrate surface.

Then, as illustrated in FIG. 8C, a silicon nitride film 240 is formed on the entire surface by CVD so as to fill space remaining above the embedded gate electrodes 410.

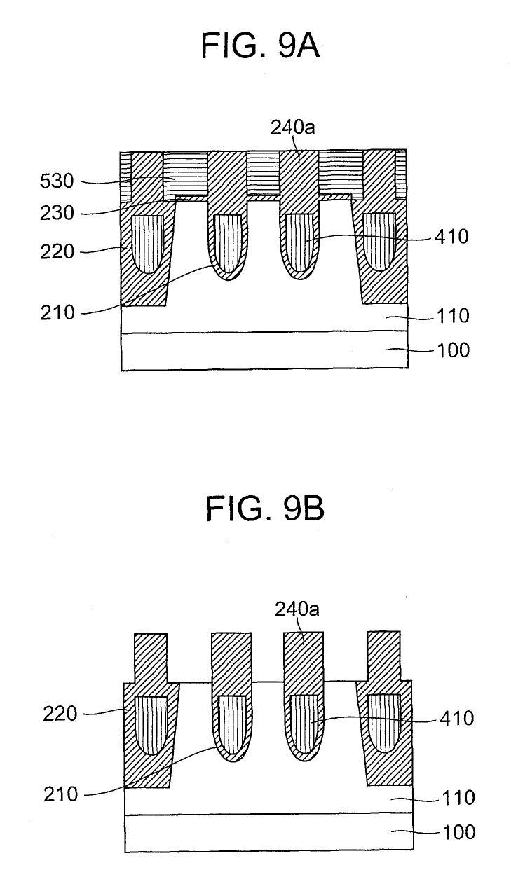

Next, as illustrated in FIG. 9A, a surface of the silicon nitride film 240 is polished by chemical mechanical polishing (CMP) to expose an upper surface of the silicon oxide film 530.

Then, as illustrated in FIG. 9B, the silicon oxide film 530 is removed by wet etching to form the cap insulating film 240a which is the silicon nitride film 240. The cap insulating film 240a is formed so as to protrude from the substrate surface by 20 to 30 nm. With this, the upper surfaces of the embedded gate electrodes 410 are covered with the cap insulating film 240a which is a silicon nitride film. Further, the upper surface of the substrate 100 in which the diffusion layer regions are to be formed are exposed in the active regions 200 in which the cap insulating film 240a is not formed.

Next, as illustrated in FIG. 10A, an opening pattern 620a, which is formed of a photoresist 620 and is opened only at a location in which the diffusion layer region 320 is to be formed, is formed by lithography. After that, for example, P is ion implanted at a dose of 1E14 atoms/cm² with a low energy of 15 keV to form impurities implanted layer 320a. In this case, a lower end of the impurities implanted layer 320a is at a depth of 100 nm from the substrate surface. Note that, the opening pattern 620a may be formed with an individual hole pattern corresponding to each active region, but may also be formed with a linear pattern extending in the Y direction in which the region of the diffusion layer region 320 is opened collectively over a plurality of active regions. As the semiconductor device becomes finer, formation of individual holes by lithography becomes more difficult, and thus, the latter pattern formation is advantageous. The opening pattern 620a having openings collectively formed therein is, as shown by the broken lines of FIG. 6A, formed so that each of a left end of the pattern and a right end of the pattern are at a location which overlaps the cap insulating film. Therefore, it is not necessary to form the pattern with the minimum dimension of processing which is the limit that may be realized by lithography, and the pattern may be formed easily.

Then, as illustrated in FIG. 10B, after the opening pattern 620a is removed, the substrate is set in an annealing furnace, and annealing is carried out under conditions in which the temperature is 700° C. at which transient enhanced diffusion to be described below is caused for 180 minutes, thereby thermally diffusing the impurities (P) contained in the impurities implanted layer 320a into a lower portion of the substrate 100 to form the deep diffusion layer region 320. At the same time, the impurities are activated to form an n-type semiconductor. With this annealing, the lower end of the diffusion layer region 320 is formed at a depth of 200 nm from the substrate surface, which is at the same level as the bottommost portions of the gate trenches 410d.

Then, as illustrated in FIG. 100, P is ion implanted into the entire surface in order to form the diffusion layer regions 310a and 310b. The implantation is carried out under conditions in which the energy is 15 keV and the dose is 1E13 atoms/cm². In this case, P is implanted into the entire portions of the substrate 100 having exposed surfaces with use of the cap insulating film 240a as the mask. With regard to the diffusion layer region 320, ion implantation is carried out twice, but the implantation in this process step is low-energy and low-dose, and thus, does not affect the location of the lower end thereof. Lower ends of the diffusion layer regions 310a and 310b are formed at a depth of 80 nm from the substrate surface.

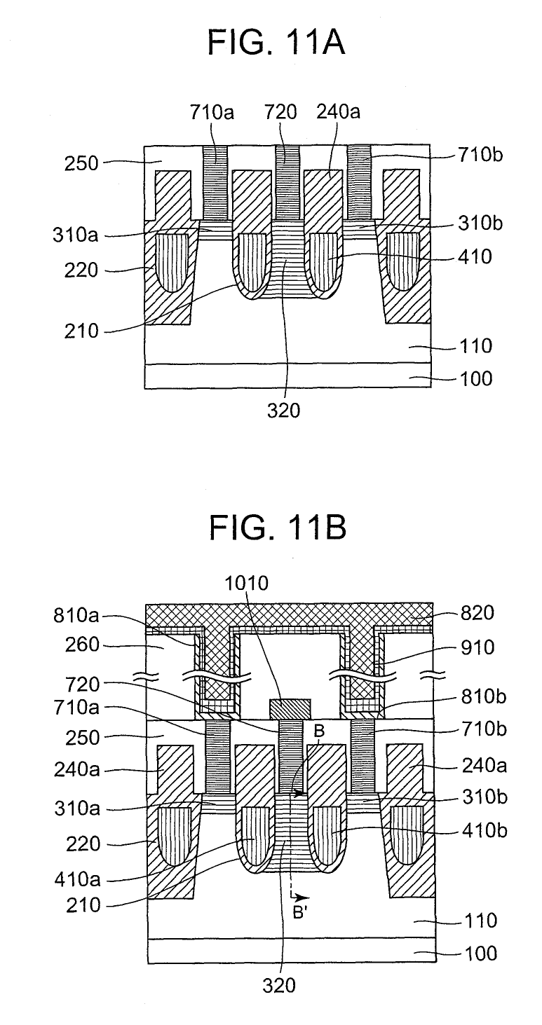

Next, as illustrated in FIG. 11A, the first interlayer insulating film 250 is formed on the entire surface of the substrate 100. After that, the bit line contact plug 720 is formed with regard to the diffusion layer region 320 to be the drain region. Further, the capacitive contact plugs 710a and 710b are formed with regard to the diffusion layer regions 310a and 310b to be the source regions, respectively.

Then, as illustrated in FIG. 11B, the bit line 1010 connected to the bit line contact plug 720 is formed on the first interlayer insulating film 250. The bit line 1010 may be formed of a stacked film of TiN and W or the like. Then, the second interlayer insulating film 260 is formed on the entire surface of the substrate 100 so as to cover the bit line 1010. After that, cylinder holes are formed by lithography and dry etching so that upper surfaces of the capacitive contact plugs 710a and 710b are exposed at the bottoms thereof. Further, the lower electrodes 810a and 810b are formed of TiN on inner surfaces of the cylinder holes. The lower electrodes 810a and 810b are connected to the capacitive contact plugs 710a and 710b, respectively. Then, the capacitive insulating film 910 is formed on the entire surface so as to cover the lower electrodes 810a and 810b, and the capacitive plate 820 is formed of TiN, W, or the like on the capacitive insulating film 910.

The first exemplary embodiment of this invention has the following effects.

The diffusion layer region 320 shared by the two transistors is formed as deep as the gate trenches 410d as illustrated in FIG. 6B, and thus, the channel regions formed in the substrate 100 in a region in which the embedded gate electrode 410a and the embedded gate electrode 410b face each other are replaced by the diffusion layer region of high concentration. Therefore, potential fluctuations caused in the channel region of the second transistor Tr2 by voltage change at the embedded gate electrode 410a of the first transistor Tr1 may be avoided.

Therefore, operation of Tr1 may be prevented from affecting the channel region of Tr2 which is adjacent to Tr1 in one active region. For example, when Tr2 is in an OFF state by the embedded gate electrode 410b, the problem in that the threshold voltage is lowered under the effect of the embedded gate electrode 410a of Tr1 and the off-leakage current increases does not arise. According to the result of experiment by the inventor of this invention, when the voltage at the embedded gate electrode 410a of Tr1 changes by 1 V, in the case of a conventional structure, the threshold voltage of Tr2 changes by as much as 20 to 30 mV, but, in the structure of this exemplary embodiment, the change in the threshold voltage is smaller than 3 mV, which presents no problem.

Further, the channel lengths of the first transistor Tr1 and the second transistor Tr2 may be set to be shorter, and at the same time, the concentration of the impurities in the deep diffusion layer region 320 is set to be higher, and thus, the parasitic resistance may be decreased, and thus, the ON current of the transistors may be increased and the performance of the semiconductor device may be improved.

Transient enhanced diffusion used in the method of manufacturing the semiconductor device according to this invention is described in the following by taking implantation of P ions as an example.

When P is ion implanted into a single crystal Si substrate, lattice damage, that is, crystal defects in which part of Si atoms forming the substrate crystal lattice is replaced by the implanted ions to become interstitial Si atoms are generated in the implanted layer. As a result, the implanted P and interstitial Si coexist in the implanted layer. When annealing is carried out at a predetermined temperature under a state in which P and interstitial Si coexist, implanted P and interstitial Si are paired, and thus, the extent of the diffusion becomes larger compared with a case where P is solely diffused.

More specifically, the implanted layer to be a crystal defect region is formed by ion implantation, and the impurities are diffused into a deeper location with the help of the defects generated in the implanted layer. This phenomenon is transient enhanced diffusion. Generally, as the semiconductor device becomes finer, a shallower diffusion layer is required. In order to form a shallow diffusion layer with high accuracy, annealing is carried out at a high temperature for a short time period so as not to cause transient enhanced diffusion. When annealing is carried out at a high temperature, crystal defects caused by ion implantation are recovered, and thus, interstitial Si disappears.

As a result, transient enhanced diffusion does not occur, and the deep diffusion layer cannot be formed. On the other hand, this invention has a feature that, by positively using transient enhanced diffusion, that is, a phenomenon in which the diffusion length becomes larger, the deep diffusion layer region is formed in annealing.

As described above, in order to cause transient enhanced diffusion, a process step of carrying out high concentration P ion implantation in the substrate surface region in which the diffusion layer region 320 is to be formed to form the implanted layer to be the defect region having crystal defects is necessary. Then, a process step of, under a state in which the heating is carried out to a temperature at which transient enhanced diffusion occurs, carrying out annealing for a time period during which at least transient enhanced diffusion is completed is necessary. More specifically, after the implanted layer to be the defect region is formed in the substrate surface by ion implantation, the substrate is inserted in an annealing furnace. A plurality of substrates which are inserted are heated to a temperature at which transient enhanced diffusion occurs, and, by carrying out annealing for a sufficiently long time period until transient enhanced diffusion of all the diffusion layers formed in the plurality of substrates is completed, the same diffusion distribution may be obtained in all the diffusion layers without being affected by the channeling distribution.

More specifically, the diffusion depth in transient enhanced diffusion is saturated after annealing is carried out for a predetermined time period, and further annealing does not cause the diffusion depth to be larger. Therefore, by carrying out annealing for a sufficiently long time period, the depths of the plurality of diffusion layers formed in the plurality of substrates may become uniform. The sufficiently long time period applied to transient enhanced diffusion is a time period of 30 minutes or more. When, as the conditions for conventional annealing, for example, 1,000° C. and 10 seconds are used, in a batch processing apparatus in which a plurality of substrates are set in a furnace body and annealing is carried out, it takes several tens of minutes for all the plurality of substrates to reach the same temperature and to be brought into a stable state, and thus, processing in a short time period such as 10 seconds cannot be accommodated. Therefore, a rapid thermal annealing (RTA) apparatus for single substrate processing which processes the substrates one by one is used. In the RTA apparatus, a lamp is used as a heat source, which enables heat treatment exhibiting abrupt thermal hysteresis.

However, annealing which is necessary for transient enhanced diffusion used in this invention is carried out for a time period as long as 30 minute or more. A single substrate processing apparatus requires an enormous amount of time, which reduces productivity, and thus, it is difficult for the RTA apparatus to accommodate annealing according to this invention. Therefore, in order to carry out this invention, annealing using a furnace body is necessary. For example, in an annealing apparatus having a vertical furnace body which may process 100 substrates, a boat in which 100 substrates are set moves upward into the furnace body having a temperature that is held at a predetermined level. The thermal capacity of the boat in which 100 substrates are set is extremely large, and thus, the temperature of the furnace body fluctuates during the boat is inserted thereinto. In order to suppress the fluctuations, it takes, for example, 40 minutes to insert the boat into the furnace body. It follows that, when the temperature of the substrate located at the lowermost portion of the boat reaches the predetermined temperature, the substrate located at the uppermost portion of the boat has been subject to annealing at least for 40 minutes. Further, even when the insertion is completed, substrates located in a lower portion are not in a stable state at the predetermined temperature, and thus, 20 minutes are additionally necessary for the temperature to be stable. When a time period taken to complete transient enhanced diffusion is, for example, 30 minutes, if annealing is carried out for 30 minutes after insertion of the boat is completed, there may be a case where, while transient enhanced diffusion of a substrate located in an upper portion of the boat is completed, transient enhanced diffusion of a substrate located in a lower portion of the boat is not completed. Therefore, annealing is carried out for a sufficiently long time period of at least 100 minutes until transient enhanced diffusion of a diffusion layer formed in a substrate located in a lower portion of the boat is completed. In this case, a substrate located in an upper portion of the boat is subject to annealing for a longer time period, but, as described above, after transient enhanced diffusion is completed, further diffusion is no longer caused even if further annealing is carried out, and thus, the depths of the plurality of diffusion layers may become uniform in a self-aligning manner.

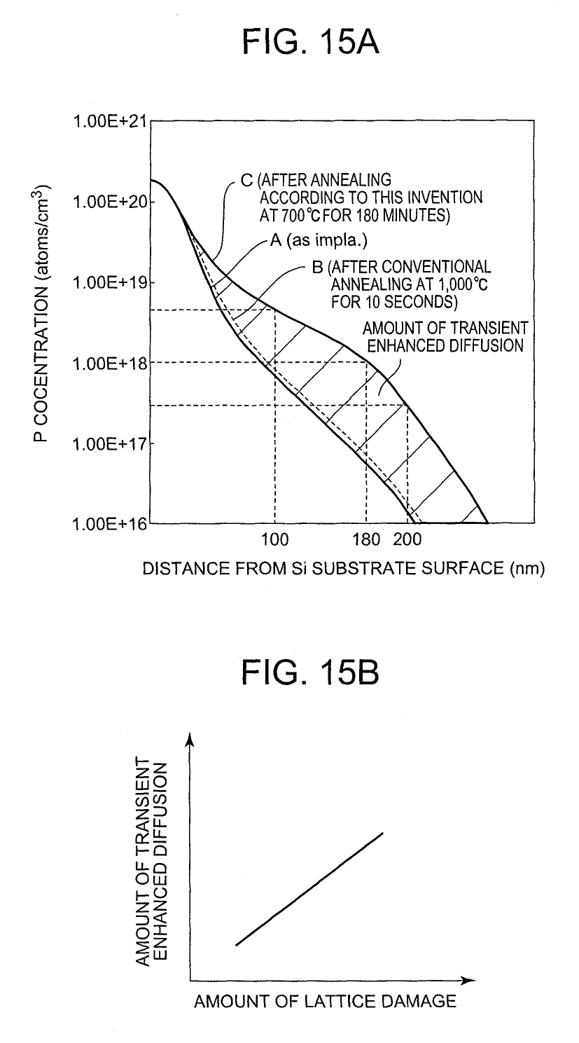

FIG. 15A shows a difference in impurities concentration distribution between conventional annealing and annealing using transient enhanced diffusion according to this invention. FIG. 15A shows P concentration distribution after the P ions are implanted and before annealing is carried out (A: as impla), P concentration distribution after conventional annealing is carried out under conditions of 1,000° C. and 10 seconds (B), and P concentration distribution after annealing according to this invention is carried out under annealing conditions of 700° C. and 180 minutes (C).

When annealing is carried out under the annealing conditions of 700° C. and 180 minutes, P is diffused to a deep location due to transient enhanced diffusion. On the other hand, P concentration distribution after conventional annealing under the conditions of 1,000° C. and 10 seconds is almost the same as concentration distribution after the ion implantation. For example, comparison is made when the P concentration is 3E17 atoms/cm³. While diffusion by the conventional annealing is only to a depth of 130 nm, diffusion by the annealing according to this invention is to a depth of 200 nm. In this case, the difference in P concentration distribution before and after the annealing is the amount of transient enhanced diffusion.

Further, it is known that, as shown in FIG. 15B, the amount of transient enhanced diffusion is in proportion to the amount of lattice damage. Therefore, when the dose of P ions is increased to increase the amount of lattice damage due to ion implantation, the amount of transient enhanced diffusion increases and a deeper diffusion layer may be formed.

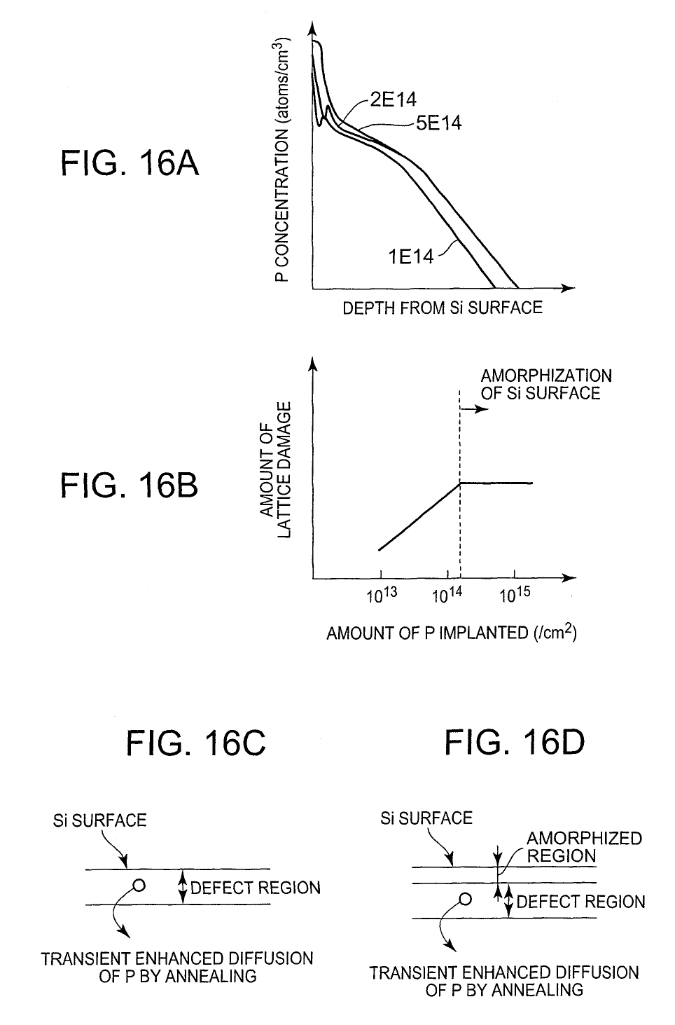

FIG. 16A shows P concentration distribution in a Si substrate when P is ion-implanted with various doses and annealing is carried out at a temperature for a time period with which transient enhanced diffusion occurs. The ion implantation is carried out with the dose being 1E14, 2E14, and 5E14 atoms/cm². Comparison is made between P concentration distribution when the dose is 1E14 atoms/cm² and P concentration distribution when the dose is 2E14 atoms/cm². It is clear that P is diffused to a deeper location from the Si surface when the dose is 2E14 atoms/cm². This is because lattice damage increases as the amount of implanted ions increases, and thus, the amount of transient enhanced diffusion increases.

Next, comparison is made between concentration distribution when the dose is 2E14 atoms/cm² and concentration distribution when the dose is 5E14 atoms/cm². Distribution in the depth direction is substantially the same. The reason is shown in FIG. 16D. When the dose is 5E14 atoms/cm², the dose is large, and thus, it is difficult to maintain crystallinity in the Si surface and the amorphization proceeds, and therefore, even though the dose is large, the amount of lattice damage in the defect region is the same. When the amount of lattice damage is the same, the amount of enhanced diffusion is the same, and the P concentration distribution in the depth direction when the dose is 2E14 atoms/cm² and the P concentration distribution in the depth direction when the dose is 5E14 atoms/cm² are substantially the same.

On the other hand, when the dose is 2E14 atoms/cm² or smaller, as illustrated in FIG. 16C, no amorphous region is formed, and only a defect region is formed. As a result, lattice damage contained in the defect region and the implanted P are coupled to cause transient enhanced diffusion.

FIG. 16B is a graph showing the relationship between the amount of lattice damage and the amount of implanted ions. From the results, it can be seen that, as the amount of implanted P ions becomes larger, P and lattice damage are paired more efficiently and enhanced diffusion occurs more effectively, and thus, the amount of transient enhanced diffusion increases and a deeper diffusion layer may be formed. However, even if the dose is larger than 2E14 atoms/cm², the diffusion layer does not become deeper.

Other than the above-mentioned lattice damage by ion implantation, Si substrate surface may be damaged by etching in a process step previous to the implantation or the like, but the amount of such damage is smaller than the lattice damage due to ion implantation, and thus, the method of forming a deep diffusion layer by using transient enhanced diffusion according to the exemplary embodiment of this invention is not affected.

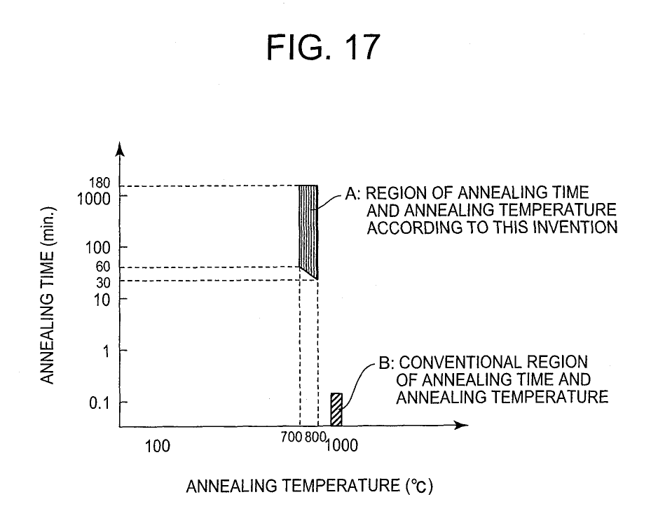

FIG. 17 shows a region A of the annealing temperature and time used in this invention. According to the exemplary embodiment of this invention, in order to form a deep diffusion layer by using transient enhanced diffusion, the temperature is required to be in a range of 700° C. to 800° C. inclusive. If the temperature is lower than 700° C., sufficient transient enhanced diffusion does not occur, and thus, a deep diffusion layer cannot be formed. If the temperature is higher than 800° C., defects contained in the implanted layer disappear, and thus, transient enhanced diffusion does not occur and a deep diffusion layer cannot be formed. Further, heat treatment for a long time at a temperature higher than 800° C. causes deterioration of insulation of the gate insulating film located adjacent to the embedded gate electrodes formed of a metal and shifts the threshold values of the transistors, which are not preferred. Further, conventionally used annealing which is carried out under conditions in which the temperature is in a range of 900° C. to 1,050° C. inclusive and the time period is about 10 seconds (B) does not cause transient enhanced diffusion, and thus, a deep diffusion layer cannot be formed.

In the above-mentioned temperature range, a time period necessary for transient enhanced diffusion to be completed depends on the temperature. For example, when the temperature is 700° C., annealing for at least 60 minutes may complete transient enhanced diffusion. When the temperature is 800° C., annealing for at least 30 minutes may complete transient enhanced diffusion. When the temperature is 800° C., if the annealing time is shorter than 30 minutes, transient enhanced diffusion is not completed and variations in depth are caused over the plurality of diffusion layers, which is not preferred. Further, as described above, annealing using a furnace body is necessary to cause transient enhanced diffusion. The temperature varies when a plurality of substrates are annealed at the same time and it takes time for the temperature to stabilize, and thus, it is preferred to carry out annealing for a time period which is longer than 30 minutes.

As described above, even if annealing is carried out at the same temperature for a time period which is longer than 30 minutes, the diffusion depth determined by the transient enhanced diffusion does not change, and thus, the diffusion depths may become uniform over the plurality of substrates. However, if the time period is longer than 180 minutes, the concentration distribution in the p-well which has been already formed in the substrate changes, and thus, the threshold values of the transistors vary in the substrate surface and between substrates, which causes fluctuations in the characteristics and which is thus not preferred. Further, that the time period exceeds 180 minutes means that the annealing apparatus is occupied for at least 180 minutes when one lot is processed, and thus, it is impossible to process a large number of lots in a day. Therefore, from the viewpoint of mass production, annealing conditions of longer than 180 minutes cannot be adopted. It is thus preferred that the annealing time be in a range of 30 to 180 minutes. As the temperature becomes higher, the diffusion rate in transient enhanced diffusion becomes higher, and thus, annealing at a higher temperature may cause the diffusion depth to be larger.

Accordingly, depending on the depths of the gate trenches which is a matter of design choice, the annealing temperature may be appropriately selected within a range of 700 to 800° C. In this way, the depths of the diffusion layers formed by using transient enhanced diffusion may be controlled by the annealing temperature and the above-mentioned dose of implanted ions.

As described above, according to the exemplary embodiment of this embodiment, the method of manufacturing a semiconductor device is provided which includes forming the active regions 200 surrounded by the element isolation regions 220, forming the plurality of gate trenches 410d so that two of the gate trenches intersect one active region 200, forming the embedded gate electrodes 410 in the plurality of gate trenches 410d, forming the cap insulating film 240a for covering the upper surfaces of the embedded gate electrodes 410, ion-implanting high concentration impurities into the semiconductor substrate surface located between the two of the gate trenches formed in the one active region to form an implanted layer in which the implanted impurities and crystal defects coexist, and thermally diffusing the implanted impurities to the depth of the bottom portions of the gate trenches by using transient enhanced diffusion with the help of the crystal defects to form the diffusion layer region 320.

According to the above-mentioned method of manufacturing a semiconductor device, the impurities are thermally diffused to the depth of the bottom portions of the gate trenches by using transient enhanced diffusion to form the diffusion layer region to be the drains of the transistors, and thus, there is an effect that it is possible to avoid the problem of the related art illustrated in FIG. 1B in that voltage change at the gate electrode 410a of the first transistor Tr.1 greatly affects the electrical characteristics of the second transistor Tr.2 through the depletion layer region formed below the diffusion layer region 320.

Further, according to the above-mentioned method of manufacturing a semiconductor device according to the exemplary embodiment of this invention, the impurities are thermally diffused to the depth of the bottom portions of the gate trenches by using transient enhanced diffusion to form the high concentration diffusion layer to be the drains of the transistors, and thus, there is an effect that the channel lengths become shorter, the parasitic resistance of the channels is decreased, the ON current of the transistors is increased, and the performance may be improved.

Further, conventionally, when the ion implantation energy is set to be higher in order to form a deep diffusion layer region by ion implantation, the ions are diffused and implanted also into the adjacent diffusion layer regions 310a and 310b in each of which a shallow diffusion layer is to be formed, and thus, there are problems in that the threshold voltage is lowered, the junction field increases, and diffusion layer leakage current increases.

However, according to the above-mentioned method of manufacturing a semiconductor device according to the exemplary embodiment of this invention, the impurities are thermally diffused to the depth of the bottom portions of the gate trenches by using transient enhanced diffusion to form the high concentration diffusion layer to be the drains of the transistors. In other words, the deep diffusion layer may be formed without using ion implantation. Therefore, there is an effect that the above-mentioned problems may be avoided.

In this exemplary embodiment, by implanting high concentration impurities ions in a region having such a depth that does not cause diffusion and implantation, that is, in a shallow region in proximity to the substrate surface, and after that, carrying out annealing at a temperature at which transient enhanced diffusion occurs, the implanted impurities are thermally diffused and a deep diffusion layer is formed only in a substrate region below the bit line contact plug. With this, there are provided a semiconductor device and a method of manufacturing the same which are capable of preventing voltage change at a gate electrode of a transistor from affecting a gate electrode of an adjacent transistor. Further, there are provided a semiconductor device and a method of manufacturing the same which are capable of improving the performance of a transistor.

### SECOND EXEMPLARY EMBODIMENT

Next, a structure of a semiconductor device and a method of manufacturing the semiconductor device according to a second exemplary embodiment of this invention are described.

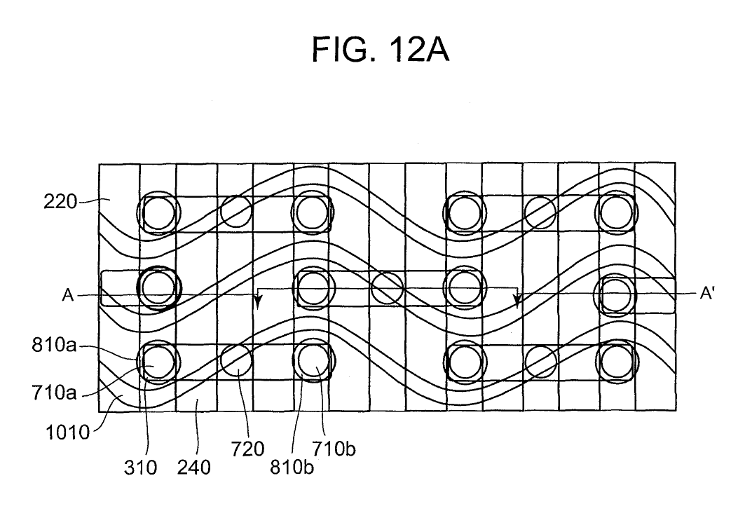

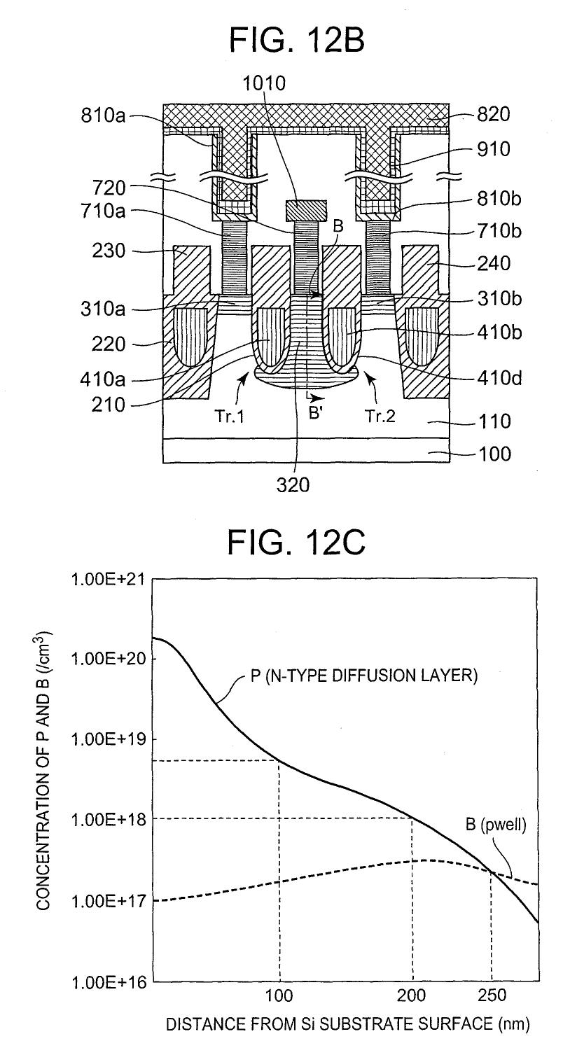

FIG. 12A is a top view of a memory cell portion of a DRAM according to the second exemplary embodiment. FIG. 12B is a sectional view taken along the line A-A′ of FIG. 12A. FIG. 12C is a graph showing concentration distribution of impurities in the section taken along the line B-B′ of FIG. 12B.

The second exemplary embodiment has a structure which is similar to that of the first embodiment, but, as illustrated in FIG. 12B, the shape of the diffusion layer region 320 is different. More specifically, the diffusion layer region 320 is formed so that a lower end thereof covers regions below the gate trenches 410d (embedded gate electrodes 410a and 410b).

FIG. 12C shows impurities concentration distribution of the diffusion layer region 320.

As shown in FIG. 12C, with the help of transient enhanced diffusion, the phosphorus concentration distribution is deeper than the phosphorus concentration distribution shown in FIG. 6C. More specifically, at a depth of 100 nm from the substrate surface, the concentration is 5E18 atoms/cm³, while, at a depth of 200 nm, the concentration is 1E18 atoms/cm³. When the peak concentration of B in the p-well is 3E17 atoms/cm³, the B concentration in the p-well and the P concentration in the n-type diffusion layer intersect each other at a depth of 250 nm shown in FIG. 12C. A pn junction boundary is at this depth, and thus, this depth is the depth of the diffusion layer region 320 of FIG. 12B.

In the method of manufacturing the semiconductor device according to the second exemplary embodiment of this invention, after P is implanted at a concentration of 2E14 atoms/cm² which is higher than that in the method of manufacturing the semiconductor device according to the first exemplary embodiment, annealing is carried out at 700° C. for 180 minutes to form the diffusion layer region 320 which is deeper than that in the first exemplary embodiment.

In this case, because the diffusion layer region 320 becomes deeper so as to cover the regions below the gate electrodes 410a and 410b, the channel lengths of Tr1 and Tr2 are shorter than those in the first embodiment, and at the same time, the concentration of the impurities in the deep diffusion layer region 320 is high, and thus, the parasitic resistance is further decreased and the ON current is improved. Further, the diffusion layer region 320 is a high concentration n-type impurity region of 1E18 atoms/cm³ or more, and thus, even when the voltage at the embedded gate electrode 410a of Tr1 changes, not only the potential distribution of a side of the embedded gate electrode 410b on the Tr2 side but also the potential distribution of the diffusion layer region 320 below does not change, and thus, effect on the electrical characteristics of

Tr2 may be avoided. Therefore, for example, even when the gate voltage of Tr1 greatly changes by about 1.5 V, the off-leakage current does not increase when the Tr2 is in an OFF state.

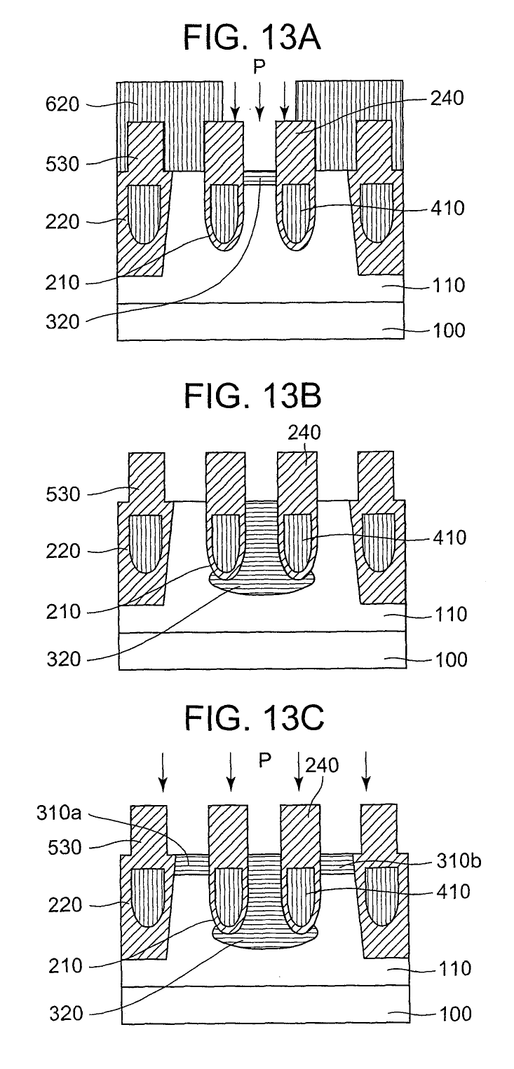

In the method of manufacturing the semiconductor device according to the second exemplary embodiment, after the manufacture proceeds up to FIG. 4C similarly to the case of the first embodiment, as illustrated in FIG. 13A, a resist pattern is formed that is opened only at a location in which the diffusion layer region 320 is to be formed, and P is implanted with a low energy at a higher concentration (2E14 atoms/cm²) than in the case of the first exemplary embodiment.

Then, as illustrated in FIG. 13B, annealing is carried out under conditions in which the temperature is 700° C. at which transient enhanced diffusion occurs for 180 minutes to form the deep diffusion layer region 320.

Then, as illustrated in FIG. 13C, P is implanted in order to form the diffusion layer regions 310a and 310b.

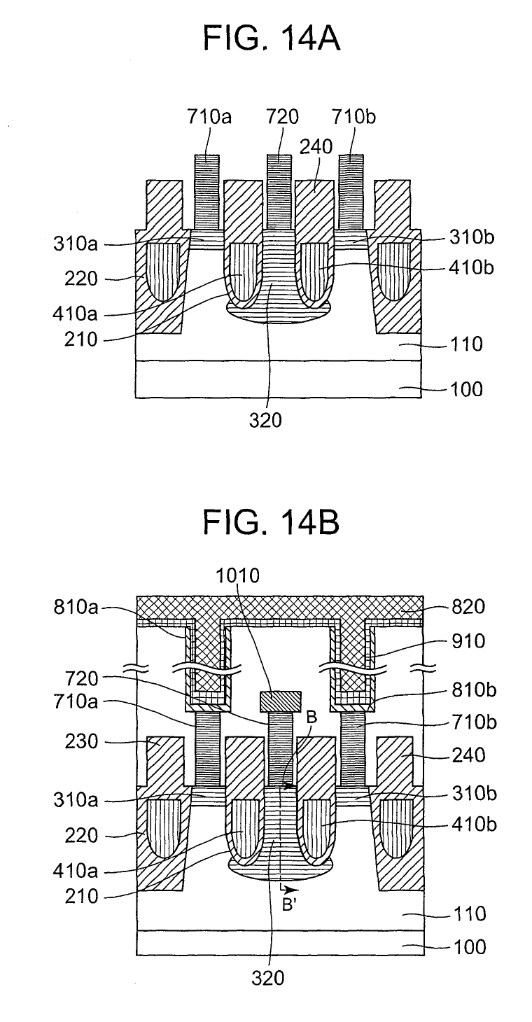

Next, as illustrated in FIG. 14A, annealing is carried out to form the cell contacts 710a and 710b and the bit contact 720.

Then, as illustrated in FIG. 14B, the bit line 1010 connected to the bit line contact plug 720 is formed. The bit line 1010 may be formed of a stacked film of TiN and W or the like. After that, cylinder holes are formed by lithography and dry etching so that upper surfaces of the capacitive contact plugs 710a and 710b are exposed at the bottoms thereof. Further, the lower electrodes 810a and 810b are formed of TiN on inner surfaces of the cylinder holes. The lower electrodes 810a and 810b are connected to the capacitive contact plugs 710a and 710b, respectively. Then, the capacitive insulating film 910 is formed on the entire surface so as to cover the lower electrodes 810a and 810b, and the capacitive plate 820 is formed of TiN, W, or the like on the capacitive insulating film 910.

As described above, according to the exemplary embodiments of this invention, by implanting high concentration ions in a shallow region, and after that, by carrying out annealing at a temperature at which transient enhanced diffusion is occurred for a time period during which at least transient enhanced diffusion is completed, a deep diffusion layer region is formed only in a substrate region below the bit line contact plug. This prevents voltage change at an embedded gate electrode of a transistor from affecting an embedded gate electrode of an adjacent transistor in one active region. Further, the semiconductor device and the method of manufacturing the same are provided, which are capable of improving the performance of a transistor.

Exemplary embodiments of this invention are described above, but it should be understood that this invention is not limited to the above-mentioned embodiments, and various modifications are possible without departing from the gist of this invention, which are also within the scope of this invention.

What is claimed is:

1. A method of manufacturing a semiconductor device, comprising:
forming an active region surrounded by an element isolation region in a substrate;
forming a pair of gate trenches in the active region;
forming a pair of gate electrodes by embedding a conductor in the gate trenches;
forming an implanted layer by implanting ions into a substrate surface between the gate electrodes; and
thermally diffusing impurities of the implanted layer at least to a depth of bottom portions of the gate trenches by a transient enhanced diffusion method to form a diffusion layer region between the gate electrodes at least to a depth of bottom portions of the gate electrodes.

2. A method according to claim 1, wherein the transient enhanced diffusion method is carried out by annealing within such a temperature range that transient enhanced diffusion occurs and within such a time range that the transient enhanced diffusion is completed.

3. A method according to claim 2, wherein the annealing activates the impurities of the implanted layer to form an n-type impurity region.

4. A method according to claim 2, wherein the temperature range of the annealing falls within a range of 700 to 800° C. while the time range of the annealing falls within a range of 30 to 180 minutes.

5. A method according to claim 2, wherein a depth of the diffusion layer region formed by the transient enhanced diffusion method is controlled depending upon a temperature of the annealing and a dose of the ions in the implantating.

6. A method according to claim 1, wherein the diffusion layer region is formed only in a substrate region below a bit line contact plug.

7. A method according to claim 1, wherein the diffusion layer region prevents voltage change at one of the gate electrodes from affecting another of the gate electrodes between a pair of transistors adjacent to each other via the diffusion layer region.

8. A method according to claim 1, wherein the diffusion layer region is formed to a depth so as to cover the bottom portions of the gate trenches.

9. A method according to claim 6, further comprising forming a bit line on the bit line contact plug.

10. A method according to claim 3, wherein the n-type impurity region has a concentration of 1E18 atoms/cm³ or more.

11. A method according to claim 3, wherein the n-type impurity region is formed so as to shorten a channel length of a transistor and decrease a parasitic resistance of the channel, thereby increasing an ON current of the transistor.

12. A method according to claim 1, wherein the implanted layer comprises the implanted impurities and crystal defects so that the diffusion layer region is formed via the crystal defects by the transient enhanced diffusion method.

13. A method according to claim 7, wherein the diffusion layer region serves as a drain region common to both of the transistors.
